(19) United States
(12) Patent Application Publication
(10) Pub. No.: US 2024/0161986 A1
(43) Pub. Date: May 16, 2024

(54) SWITCH DEVICE AND OPERATING METHOD THEREOF

(71) Applicants: Chunghui KANG, Taipei City (TW); Chihkuo CHUI, Taoyuan City (TW); Jui-Ling LEE, New Taipei City (TW)

(72) Inventors: Chunghui KANG, Taipei City (TW); Chihkuo CHUI, Taoyuan City (TW); Jui-Ling LEE, New Taipei City (TW)

(21) Appl. No.: 18/241,864

(22) Filed: Sep. 2, 2023

(30) Foreign Application Priority Data
Nov. 15, 2022 (TW) 111143648

(51) Int. Cl. H01H 13/803; H01H 13/7073

(52) U.S. Cl. CPC H01H 13/803; H01H 13/7073; H01H 2235/00; H01H 2239/024

(57) ABSTRACT

A switch device includes at least one spring, a sliding body and a circuit board. The at least one spring is configured to generate a switch signal corresponding to an inductance of the at least one spring, and includes a first spring portion and a second spring portion arranged along a first direction. The inductance is associated with a first interval between the first spring portion and the second spring portion. The sliding body is configured to move along the first direction to change the first interval. The circuit board is configured to receive the switch signal. The at least one spring is located between the sliding body and the circuit board.

### CROSS-REFERENCE TO RELATED APPLICATION

This application claims priority to Taiwan Application Serial Number 111143648, filed Nov. 15, 2022, which is herein incorporated by reference in its entirety.

### BACKGROUND

### Technical Field

The present disclosure relates to a switch technique. More particularly, the present disclosure relates to a switch device and a method of operating a switch device.

### Description of Related Art

Buttons of a keyboard can be constructed by Hall sensing switches, optical switches or mechanical switches. However, optical elements required by the optical switches are more, such that the cost is higher and the degree of freedom of designing is lower. The mechanical switches cannot provide switch signals of states other than a pressed state and an unpressed state. Thus, techniques associated with the designing for overcoming the problems described above are important issues in the field.

### SUMMARY

The present disclosure provides a switch device. The switch device includes at least one spring, a sliding body and a circuit board. The at least one spring is configured to generate a switch signal corresponding to an inductance of the at least one spring, and includes a first spring portion and a second spring portion arranged along a first direction. The inductance is associated with a first interval between the first spring portion and the second spring portion. The sliding body is configured to move along the first direction to change the first interval. The circuit board is configured to receive the switch signal. The at least one spring is located between the sliding body and the circuit board.

The present disclosure provides a switch device. The switch device includes a magnetizer, a coil structure, a slide body and a circuit board. The coil structure includes a plurality of first conductive lines and a plurality of second conductive lines, is formed as an inductor with the magnetizer, and is configured to generate a switch signal according to the inductor. The slide body is configured to move the magnetizer to change the inductor. The circuit board is located between the plurality of first conductive lines and the plurality of second conductive lines, and is configured to receive the switch signal.

The present disclosure provides a method of operating a switch device. The method includes: pressing at least one spring to adjust a first interval between a first spring portion of the at least one spring and a second spring portion of the at least one spring; generating a switch signal having a first current value from the spring to a circuit board when the first interval has a first length; and generating the switch signal having a second current value from the spring to the circuit board when the first interval has a second length. The first current value is different from the second current value, and the first length is different from the second length.

It is to be understood that both the foregoing general description and the following detailed description are examples, and are intended to provide further explanation of the disclosure as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is an exploded diagram of a switch device illustrated according to some embodiments of present disclosure.

FIG. 1B is a three-dimension structural diagram of the switch device illustrated according to some embodiments of present disclosure.

FIG. 1C and FIG. 1D are two-dimension cross section diagrams of the switch device illustrated according to some embodiments of present disclosure.

FIG. 2A is an exploded diagram of a switch device illustrated according to some embodiments of present disclosure.

FIG. 2B is a three-dimension structural diagram of the switch device illustrated according to some embodiments of present disclosure.

FIG. 2C and FIG. 2D are two-dimension cross section diagrams of the switch device illustrated according to some embodiments of present disclosure.

FIG. 3A is an exploded diagram of a switch device illustrated according to some embodiments of present disclosure.

FIG. 3B is a three-dimension structural diagram of the switch device illustrated according to some embodiments of present disclosure.

FIG. 3C and FIG. 3D are two-dimension cross section diagrams of the switch device illustrated according to some embodiments of present disclosure.

FIG. 4A is an exploded diagram of a switch device illustrated according to some embodiments of present disclosure.

FIG. 4B is a three-dimension structural diagram of the switch device illustrated according to some embodiments of present disclosure.

FIG. 4C and FIG. 4D are two-dimension cross section diagrams of the switch device illustrated according to some embodiments of present disclosure.

FIG. 5A is an exploded diagram of a switch device illustrated according to some embodiments of present disclosure.

FIG. 5B is a three-dimension structural diagram of the switch device illustrated according to some embodiments of present disclosure.

FIG. 5C and FIG. 5D are two-dimension cross section diagrams of the switch device illustrated according to some embodiments of present disclosure.

FIG. 5E is a three-dimension schematic diagram of the coil structure shown in FIG. 5A, illustrated according to some embodiments of present disclosure.

FIG. 5F is a three-dimension schematic diagram of a coil structure illustrated according to some embodiments of present disclosure.

FIG. 6A is an exploded diagram of a switch device illustrated according to some embodiments of present disclosure.

FIG. 6B is a three-dimension structural diagram of the switch device illustrated according to some embodiments of present disclosure.

FIG. 6C and FIG. 6D are two-dimension cross section diagrams of the switch device illustrated according to some embodiments of present disclosure.

FIG. 7A is an exploded diagram of a switch device illustrated according to some embodiments of present disclosure.

FIG. 7B is a three-dimension structural diagram of the switch device illustrated according to some embodiments of present disclosure.

FIG. 7C is a two-dimension cross section diagram of the switch device illustrated according to some embodiments of present disclosure.

FIG. 7D is a top view diagram of the magnetizer and the coil structure shown in FIG. 7C illustrated according to some embodiments of present disclosure.

FIG. 7E is a two-dimension cross section diagram of the switch device illustrated according to some embodiments of present disclosure.

FIG. 7F is a top view diagram of the magnetizer and the coil structure shown in FIG. 7E illustrated according to some embodiments of present disclosure.

### DETAILED DESCRIPTION

In the present disclosure, when an element is referred to as “connected” or “coupled”, it may mean “electrically connected” or “electrically coupled”. “Connected” or “coupled” can also be used to indicate that two or more components operate or interact with each other. In addition, although the terms “first”, “second”, and the like are used in the present disclosure to describe different elements, the terms are used only to distinguish the elements or operations described in the same technical terms. The use of the term is not intended to be a limitation of the present disclosure.

Unless otherwise defined, all terms (including technical and scientific terms) used in the present disclosure have the same meaning as commonly understood by the ordinary skilled person to which the concept of the present invention belongs. It will be further understood that terms (such as those defined in commonly used dictionaries) should be interpreted as having a meaning consistent with its meaning in the related technology and/or the context of this specification and not it should be interpreted in an idealized or overly formal sense, unless it is clearly defined as such in this article.

The terms used in the present disclosure are only used for the purpose of describing specific embodiments and are not intended to limit the embodiments. As used in the present disclosure, the singular forms “a”, “one” and “the” are also intended to include plural forms, unless the context clearly indicates otherwise. It will be further understood that when used in this specification, the terms “comprises (comprising)” and/or “includes (including)” designate the existence of stated features, steps, operations, elements and/or components, but the existence or addition of one or more other features, steps, operations, elements, components, and/or groups thereof are not excluded.

Hereinafter multiple embodiments of the present disclosure will be disclosed with schema, as clearly stated, the details in many practices it will be explained in the following description. It should be appreciated, however, that the details in these practices is not applied to limit the present disclosure. Also, it is to say, in some embodiments of the present disclosure, the details in these practices are non-essential. In addition, for the sake of simplifying schema, some known usual structures and element in the drawings by a manner of simply illustrating for it.

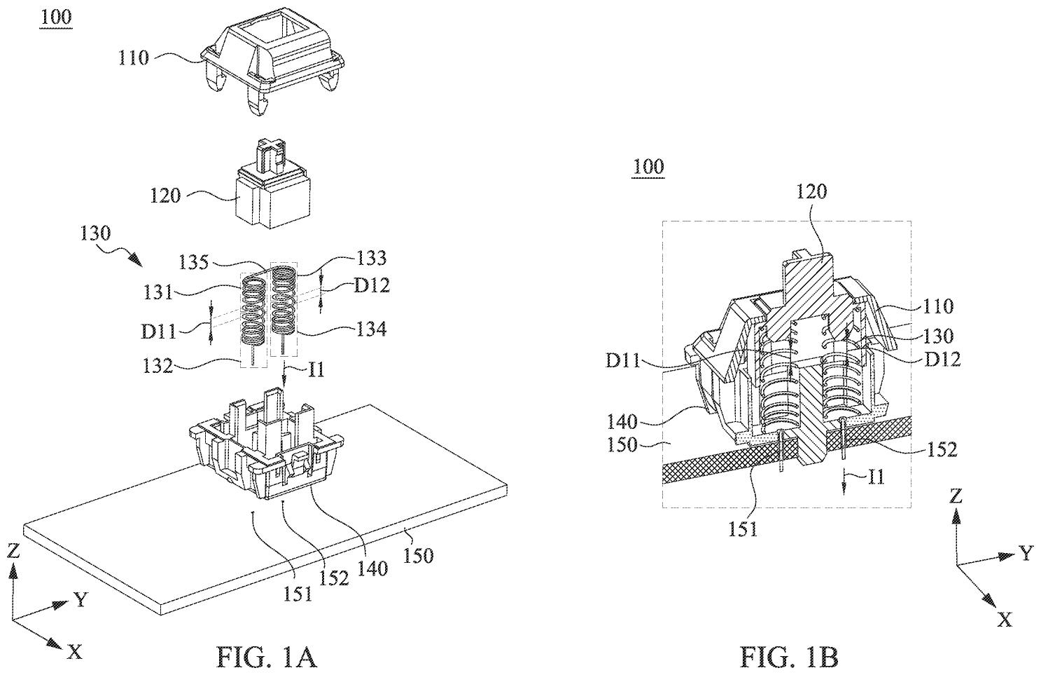

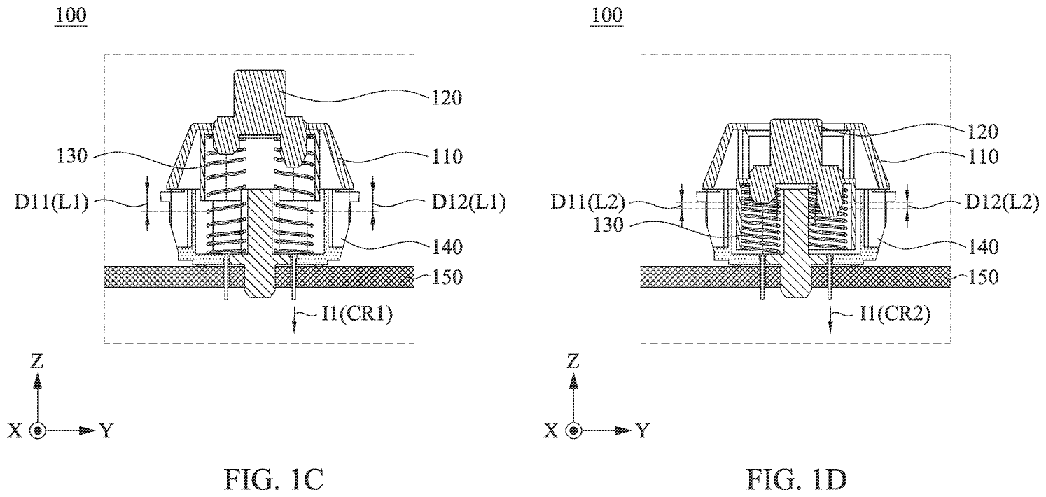

FIG. 1A is an exploded diagram of a switch device 100 illustrated according to some embodiments of present disclosure. In some embodiments, the switch device 100 is configured to be constructed as a button of a keyboard, and is configured to generate a switch signal 11 corresponding to a pressed stated and an unpressed state.

As illustratively shown in FIG. 1A, the switch device 100 includes a switch top cover 110, a slide body 120, a spring 130, a switch bottom cover 140 and a printed circuit board (PCB) 150. The PCB 150, the switch bottom cover 140, the spring 130, the slide body 120 and the switch top cover 110 are arranged in order in a Z direction. In some embodiments, the spring 130 can be implemented by metal or other conductors, and the switch top cover 110, the slide body 120, and the switch bottom cover 140 can be implemented by plastic or other insulators.

As illustratively shown in FIG. 1A, the spring 130 includes spring portions 131-134 and a connect portion 135. The spring portions 132 and 131 are arranged in order along a Z direction. The spring portions 134 and 133 are arranged in order along the Z direction. The spring portions 131 and 133 are arranged in order along a Y direction. The spring portions 132 and 134 are arranged in order along the Y direction and are separated from each other. The connect portion 135 extends along the Y direction, and is configured to connect the spring portions 131 and 133. In some embodiments, the Y direction is perpendicular to the Z direction.

As illustratively shown in FIG. 1A, along the Z direction, an interval D11 is between the spring portions 132 and 131, and an interval D12 is between the spring portions 134 and 133. In some embodiments, the spring portions 132 and 131 can be implemented by a continuous spring structure including multiple spring coils, and the spring portions 134 and 133 also can be implemented by a continuous spring structure including multiple spring coils. In the embodiments described above, each of the intervals D11 and D12 corresponds to the interval between two adjacent spring coils. In various embodiments, the spring 130 can have various shapes. In various embodiments, the magnitudes of each spring intervals may not equal, and are associated with the structure, the material and the K value of the spring 130.

In some embodiments, the spring 130 is configured to generate the switch signal 11 to the PCB 150 according to an inductance of the spring 130. The inductance of the spring 130 is associated with the intervals D11 and D12. When the intervals D11 and D12 are changed, the switch signal 11 is changed accordingly. In some embodiments, the switch signal 11 is the current signal flowing through the spring 130. The PCB 150 is configured to receive the switch signal 11, and transmit the switch signal 11 to a processor.

As illustratively shown in FIG. 1A, the PCB 150 includes holes 151 and 152. The holes 151 and 152 are arranged in order along the Y direction. The spring portion 131 can be fixed on the PCB 150 through the hole 151, and the spring portion 132 can be fixed on the PCB 150 through the hole 152.

FIG. 1B is a three-dimension structural diagram of a cross section of the switch device 100 illustrated according to some embodiments of present disclosure. As illustratively shown in FIG. 1B, each of the switch top cover 110 and the switch bottom cover 140 surrounds the slide body 120 and the spring 130 on the X-Y plane corresponding to the X direction and the Y direction. A part of the slide body 120 protrudes the switch top cover 110. In other embodiments, the slide body 120 may not protrude the switch top cover 110. In some embodiments, the X direction is perpendicular to the Y direction and the Z direction.

As illustratively shown in FIG. 1B, the slide body 120 surrounds the spring 130 on the X-Y plane, and contacts with the spring 130 along the Z direction. In some alternative embodiments, the slide body 120 can locates at a side of the spring 130 and not surround the spring 130. In some embodiments, the slide body 120 is configured to move along the Z direction to press the spring 130, such that the intervals D11 and D12 are decreased. In some embodiments, the switch bottom cover 140 is fixed on the PCB 150, and is referred to as a switch body seat. In other embodiments, the switch bottom cover 140 may not be fixed on the PCB 150. For example, the switch device 100 can further include a fixed switch structure board, and the switch bottom cover 140 is fixed on the fixed switch structure board. In some embodiments, a material of the fixed switch structure board is metal.

FIG. 1C is a two-dimension cross section diagram of the switch device 100 illustrated according to some embodiments of present disclosure. The embodiments shown in FIG. 1C correspond to the unpressed state of the switch device 100. As illustratively shown in FIG. 1C, each of the intervals D11 and D12 has a length L1. At this moment, the switch signal 11 has a current value CR1 corresponds to the length L1.

FIG. 1D is a two-dimension cross section diagram of the switch device 100 illustrated according to some embodiments of present disclosure. The embodiments shown in FIG. 1D correspond to the pressed state of the switch device 100. As illustratively shown in FIG. 1D, each of the intervals D11 and D12 has a length L2. At this moment, the switch signal 11 has a current value CR2 corresponds to the length L2. In some embodiments, the length L2 is smaller than the length L1. In various embodiments, the current value CR1 corresponds to unpressed states of various switch devices (such as the switch devices 100, 200, 300, 400, 500, 600 and 700 shown in FIG. 1A to FIG. 7A), and the current value CR2 corresponds to pressed states of the various switch devices.

Referring to FIG. 1D and FIG. 1C, the slide body 120 is configured to move along a negative Z direction (that is, an inverse direction of the Z direction), to change from the unpressed state shown in FIG. 1C to the pressed state shown in FIG. 1D, and is configured to move along the Z direction to change from the pressed state to the unpressed state.

In some embodiments, the switch device 100 can further has states between the pressed state to the unpressed state. In the embodiments described above, each of the interval D11 and D12 has a length between the lengths L1 and L2, and a current value of the switch device 11 is between the current values CR1 and CR2.

In some approaches an inductor of a switch device includes a coil and a magnetizer passing through the coil. A space occupied by the coil and the magnetizer is larger, a degree of freedom of designing is lower and the cost is higher.

Compared to above approaches, the switch device 100 generates the switch signal 11 according to the spring 130 itself. Additional elements are not required, such that a required space is smaller, a degree of freedom of designing is higher and the cost is lower.

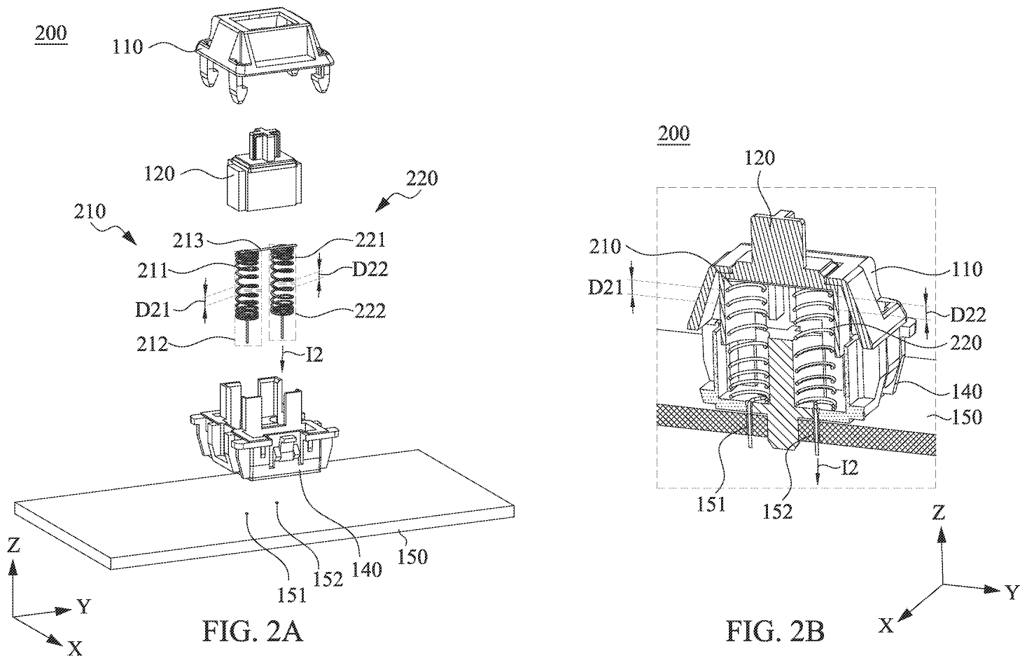

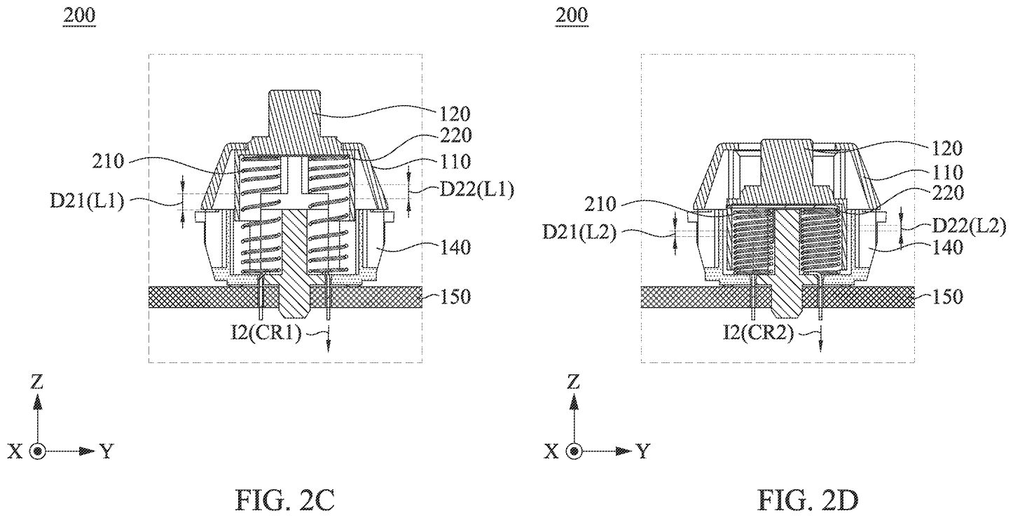

FIG. 2A is an exploded diagram of a switch device 200 illustrated according to some embodiments of present disclosure. Referring to FIG. 2A and FIG. 1A, the switch device 200 is an alternative embodiment of the switch 100. Some elements of the switch device 200 follows a similar labeling convention to that of the switch device 100. For brevity, the discussion will focus more on differences between the switch device 200 and the switch device 100 than on similarities.

Referring to FIG. 2A and FIG. 1A, the switch device 200 includes springs 210 and 220 instead of the spring 130. Along the Z direction, each of the springs 210 and 220 is located between the slide body 120 and the switch bottom cover 140. In some embodiments, the each of the springs 210 and 220 can be implemented by metal or other conductors.

As illustratively shown in FIG. 2A, the spring 210 includes a contact portion 213, spring portions 211 and 212. The spring 220 includes spring portions 221 and 222. The spring portions 212 and 211 are arranged in order along the Z direction. The spring portions 222 and 221 are arranged in order along the Z direction. The spring portions 212 and 222 are arranged in order along the Y direction and are separated from each other. A terminal of the contact portion 213 is connected to the spring portion 211. The contact portion 213 extends along the Y direction, and contacts with the spring portion 221, such that the spring portions 211 and 221 are coupled in series through the contact. In some embodiments, along the Y direction, a length of the contact portion 213 is longer than a distance between the spring portions 212 and 222.

As illustratively shown in FIG. 2A, along the Z direction, an interval D21 is between the spring portions 211 and 212, and an interval D22 is between the spring portions 221 and 222. In some embodiments, the springs 210 and 220 can be implemented by continuous spring structures including multiple spring coils. In the embodiments described above, each of the intervals D21 and D22 corresponds to the interval between two adjacent spring coils. In various embodiments, the springs 210 and 220 can have various shapes.

In some embodiments, the springs 210 and 220 are configured to generate the switch signal 12 to the PCB 150 according to an inductance of the springs 210 and 220. The inductance of the springs 210 and 220 is associated with the intervals D21 and D22. When the intervals D21 and D22 are changed, the switch signal 12 is changed accordingly. In some embodiments, the switch signal 12 is the current signal flowing through each of the springs 210 and 220. The switch signal 12 corresponds to the switch signal 11 shown in FIG. 1A. In various embodiments, the switch device 200 can include various numbers (for example, more than two) of springs. For example, the switch device 200 can include springs other than the springs 210 and 220, and can generate the switch signal 12 by the springs described above and the springs 210 and 220 together.

FIG. 2B is a three-dimension structural diagram of a cross section of the switch device 200 illustrated according to some embodiments of present disclosure. As illustratively shown in FIG. 2B, each of the switch top cover 110 and the switch bottom cover 140 surrounds the slide body 120 and the springs 210 and 220 on the X-Y plane. In some alternative embodiments, each of the switch top cover 110 and the switch bottom cover 140 can also be located at a side of the slide body 120, the springs 210 and 220 and does not surround the slide body 120, the springs 210 and 220. In some embodiments, the slide body 120 is configured to move along the Z direction to press the springs 210 and 220, such that the intervals D21 and D22 are reduced.

FIG. 2C is a two-dimension cross section diagram of the switch device 200 illustrated according to some embodiments of present disclosure. The embodiments shown in FIG. 2C correspond to the unpressed state of the switch device 200. As illustratively shown in FIG. 2C, each of the intervals D21 and D22 has the length L1. At this moment, the switch signal 12 has the current value CR1 corresponds to the length L1.

FIG. 2D is a two-dimension cross section diagram of the switch device 200 illustrated according to some embodiments of present disclosure. The embodiments shown in FIG. 2D correspond to the pressed state of the switch device 200. As illustratively shown in FIG. 2D, each of the intervals D21 and D22 has a length L2. At this moment, the switch signal 12 has a current value CR2 corresponds to the length L2. In various embodiments, the intervals D21 and D22 may be different, and the intervals D21 and D22 are associated with the structures, material and K values of the springs 210 and 220. For example, when the switch device 200 is unpressed, one of the intervals D21 and D22 has the length L1, and the other one of the intervals D21 and D22 has a length other than the length L1. When the switch device 200 is pressed, one of the intervals D21 and D22 has the length L2, and the other one of the intervals D21 and D22 has a length other than the length L2.

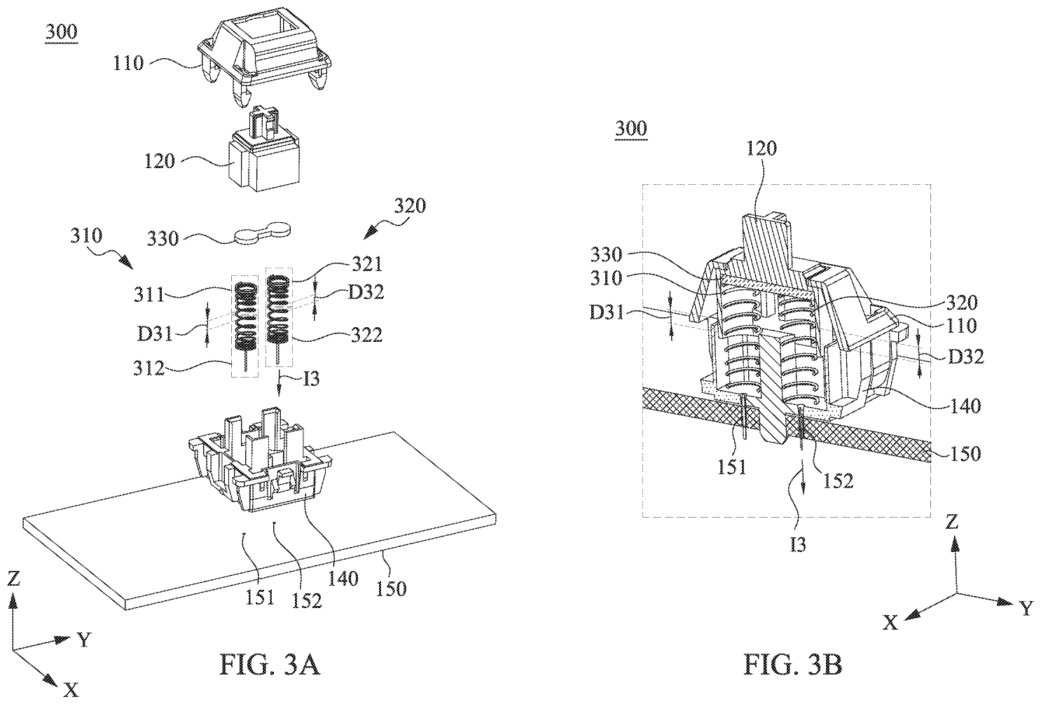

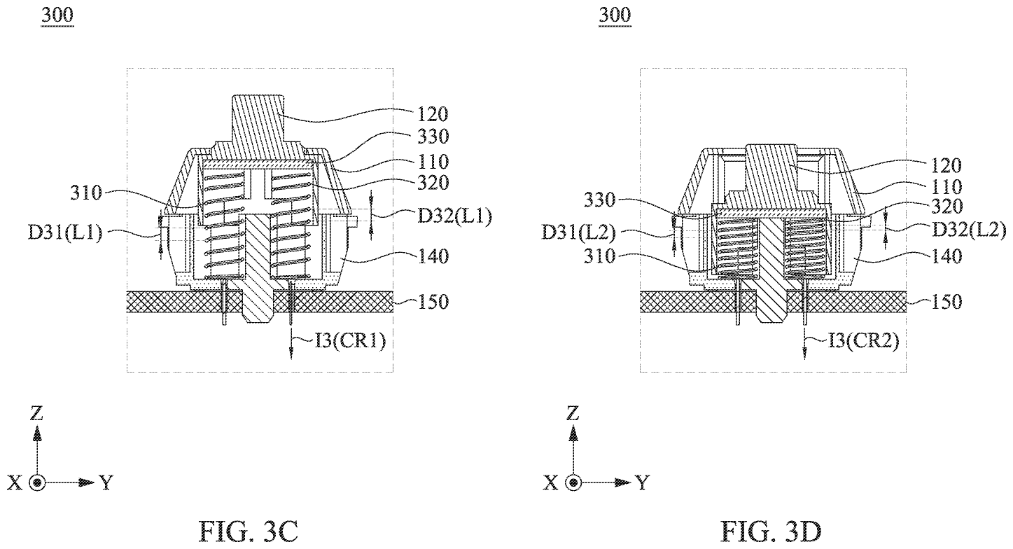

FIG. 3A is an exploded diagram of a switch device 300 illustrated according to some embodiments of present disclosure. Referring to FIG. 3A and FIG. 1A, the switch device 300 is an alternative embodiment of the switch 100. Some elements of the switch device 300 follows a similar labeling convention to that of the switch device 100. For brevity, the discussion will focus more on differences between the switch device 300 and the switch device 100 than on similarities.

Referring to FIG. 3A and FIG. 1A, the switch device 300 includes springs 310, 320 and a conductive sheet 330 instead of the spring 130. Along the Z direction, the conductive sheet 330 is located between the slide body 120 and the switch bottom cover 140, and each of the springs 310 and 320 is located between the conductive sheet 330 and the switch bottom cover 140. In some embodiments, the each of the springs 310, 320 and the conductive sheet 330 can be implemented by metal or other conductors.

As illustratively shown in FIG. 3A, the spring 310 includes spring portions 311 and 312. The spring 320 includes spring portions 321 and 322. The spring portions 312 and 311 are arranged in order along the Z direction. The spring portions 322 and 321 are arranged in order along the Z direction. The spring portions 312 and 322 are arranged in order along the Y direction and are separated from each other. A terminal of the conductive sheet 330 contacts the spring portion 311 along the Z direction, another terminal of the conductive sheet 330 contacts the spring portion 321 along the Z direction, such that the spring portions 311 and 321 are electrically coupled to each other, to couple the springs 310 and 320 are coupled in series. In some embodiments, along the Y direction, a length of the conductive sheet 330 is longer than a distance between the spring portions 312 and 322. In other embodiments, along the Y direction, a length of the conductive sheet 330 may be shorter than the distance between the spring portions 312 and 322.

As illustratively shown in FIG. 3A, along the Z direction, an interval D31 is between the spring portions 311 and 312, and an interval D32 is between the spring portions 321 and 322. In some embodiments, the springs 310 and 320 can be implemented by continuous spring structures including multiple spring coils. In the embodiments described above, each of the intervals D31 and D32 corresponds to the interval between two adjacent spring coils. In various embodiments, the springs 310 and 320 can have various shapes.

In some embodiments, the springs 310 and 320 are configured to generate the switch signal 13 to the PCB 150 according to an inductance of the springs 310 and 320. The inductance of the springs 310 and 320 is associated with the intervals D31 and D32. When the intervals D31 and D32 are changed, the switch signal 13 is changed accordingly. In some embodiments, the switch signal 13 is the current signal flowing through the conductive sheet 330 and each of the springs 310 and 320. The switch signal 13 corresponds to the switch signal 11 shown in FIG. 1A.

FIG. 3B is a three-dimension structural diagram of a cross section of the switch device 300 illustrated according to some embodiments of present disclosure. As illustratively shown in FIG. 3B, each of the switch top cover 110 and the switch bottom cover 140 surrounds the slide body 120, the conductive sheet 330, the springs 310 and 320 on the X-Y plane. The slide body 120 surrounds the conductive sheet 330, the springs 310 and 320 on the X-Y plane, and contacts the conductive sheet 330 along the Z direction. In some embodiments, the slide body 120 is configured to move along the Z direction to press the springs 310 and 320 through the conductive sheet 330, such that the intervals D31 and D32 are reduced.

FIG. 3C is a two-dimension cross section diagram of the switch device 300 illustrated according to some embodiments of present disclosure. The embodiments shown in FIG. 3C correspond to the unpressed state of the switch device 300. As illustratively shown in FIG. 3C, each of the intervals D31 and D32 has the length L1. At this moment, the switch signal 13 has the current value CR1 corresponds to the length L1.

FIG. 3D is a two-dimension cross section diagram of the switch device 300 illustrated according to some embodiments of present disclosure. The embodiments shown in FIG. 3D correspond to the pressed state of the switch device 300. As illustratively shown in FIG. 3D, each of the intervals D31 and D32 has a length L2. At this moment, the switch signal 13 has a current value CR2 corresponds to the length L2.

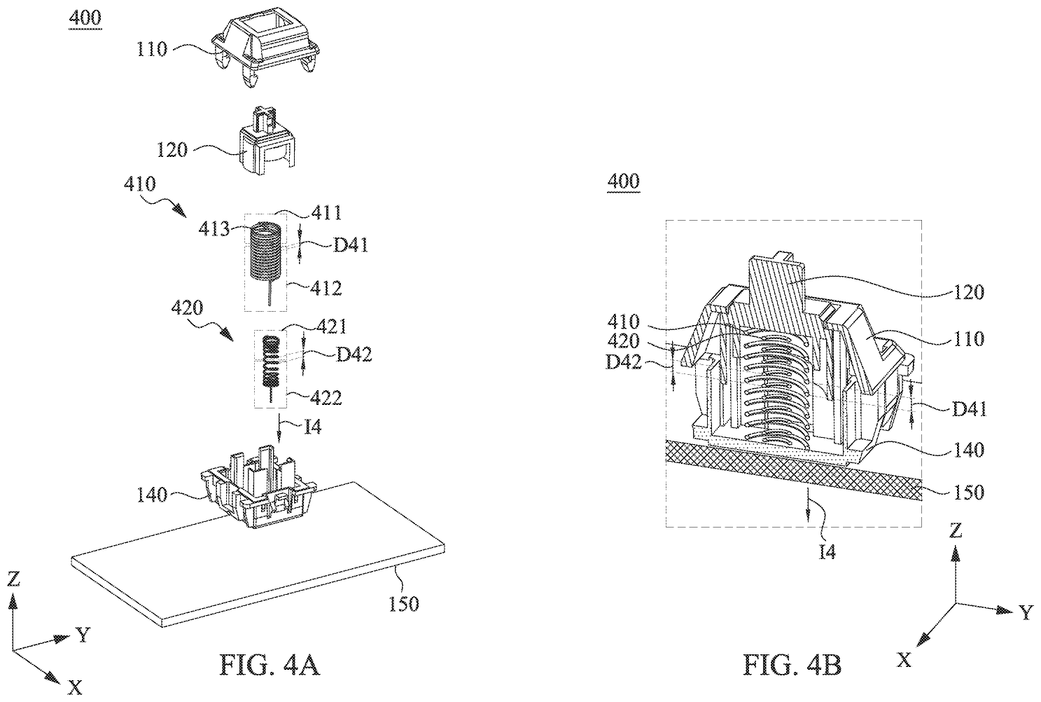

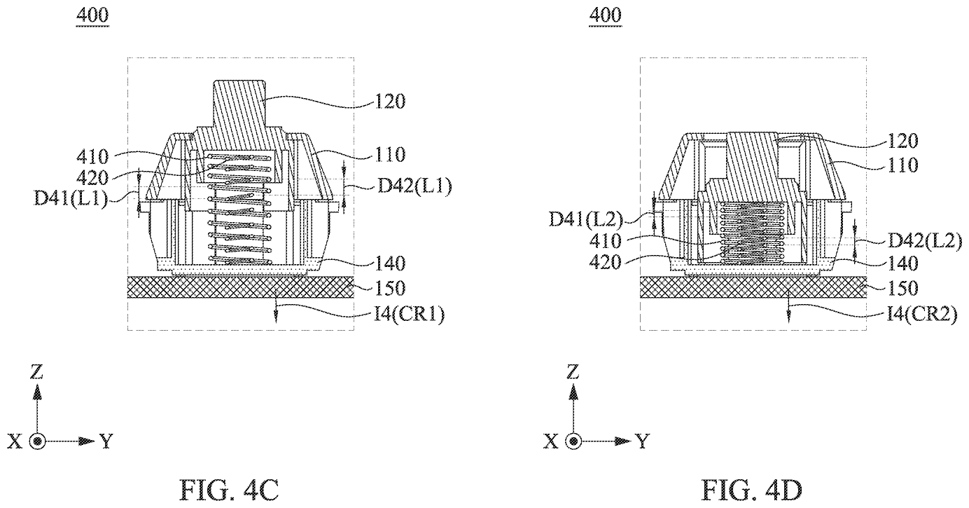

FIG. 4A is an exploded diagram of a switch device 400 illustrated according to some embodiments of present disclosure. Referring to FIG. 4A and FIG. 1A, the switch device 400 is an alternative embodiment of the switch 100. Some elements of the switch device 400 follows a similar labeling convention to that of the switch device 100. For brevity, the discussion will focus more on differences between the switch device 400 and the switch device 100 than on similarities.

Referring to FIG. 4A and FIG. 1A, the switch device 400 includes springs 410 and 420 instead of the spring 130. Along the Z direction, the each of the springs 410 and 420 is located between the slide body 120 and the switch bottom cover 140. In some embodiments, the each of the springs 410 and 420 can be implemented by metal or other conductors. In some embodiments, a size of the spring 420 is smaller than a size of the spring 410.

As illustratively shown in FIG. 4A, the spring 410 includes spring portions 411 and 412. The spring 420 includes spring portions 421 and 422. The spring portions 412 and 411 are arranged in order along the Z direction. The spring portions 422 and 421 are arranged in order along the Z direction. The spring portions 411 includes a contact portion 413. The contact portion 413 extends along the X-Y plane, and contacts the spring 420 along the Z direction, such that the springs 410 and 420 are coupled in series. In other embodiments, the spring portion 411 may not include the contact portion 413, and the switch device 400 further includes a conductive sheet similar with the conductive sheet 330 shown in FIG. 3A, to couple the springs 420 and 410 in series.

As illustratively shown in FIG. 4A, along the Z direction, an interval D41 is between the spring portions 411 and 412, and an interval D42 is between the spring portions 421 and 422. In some embodiments, the springs 410 and 420 can be implemented by continuous spring structures including multiple spring coils. In the embodiments described above, each of the intervals D41 and D42 corresponds to the interval between two adjacent spring coils. In various embodiments, the springs 410 and 420 can have various shapes.

In some embodiments, the springs 410 and 420 are configured to generate the switch signal 14 to the PCB 150 according to an inductance of the springs 410 and 420. The inductance of the springs 410 and 420 is associated with the intervals D41 and D42. When the intervals D41 and D42 are changed, the switch signal 14 is changed accordingly. In some embodiments, the switch signal 14 is the current signal flowing through each of the springs 410 and 420. The switch signal 14 corresponds to the switch signal 11 shown in FIG. 1A. In various embodiments, the switch device 400 can include various numbers (for example, more than two) of springs. For example, the switch device 400 can include springs located at outside of and surrounding the springs 410 and 420, and can generate the switch signal 14 by the springs described above and the springs 410 and 420 together.

FIG. 4B is a three-dimension structural diagram of a cross section of the switch device 400 illustrated according to some embodiments of present disclosure. As illustratively shown in FIG. 4B, each of the switch top cover 110 and the switch bottom cover 140 surrounds the slide body 120, the springs 410 and 420 on the X-Y plane. The slide body 120 surrounds the springs 410 and 420 on the X-Y plane, and contacts the springs 410 and 420 along the Z direction. In some embodiments, the slide body 120 is configured to move along the Z direction to press the springs 410 and 420, such that the intervals D41 and D42 are reduced.

As illustratively shown in FIG. 4B, the spring 410 surrounds the spring 420 on the X-Y plane. In some embodiments, the springs 410 and 420 have the same center of circle, to form a concentric circle structure, and the contact portion 413 passes through the center of circuit to contacts the spring 420. In other embodiment, the springs 410 and 420 can also formed into structures other than the concentric circle structure.

FIG. 4C is a two-dimension cross section diagram of the switch device 400 illustrated according to some embodiments of present disclosure. The embodiments shown in FIG. 4C correspond to the unpressed state of the switch device 400. As illustratively shown in FIG. 4C, each of the intervals D41 and D42 has the length L1. At this moment, the switch signal 14 has the current value CR1 corresponds to the length L1.

FIG. 4D is a two-dimension cross section diagram of the switch device 400 illustrated according to some embodiments of present disclosure. The embodiments shown in FIG. 4D correspond to the pressed state of the switch device 400. As illustratively shown in FIG. 4D, each of the intervals D41 and D42 has a length L2. At this moment, the switch signal 14 has a current value CR2 corresponds to the length L2.

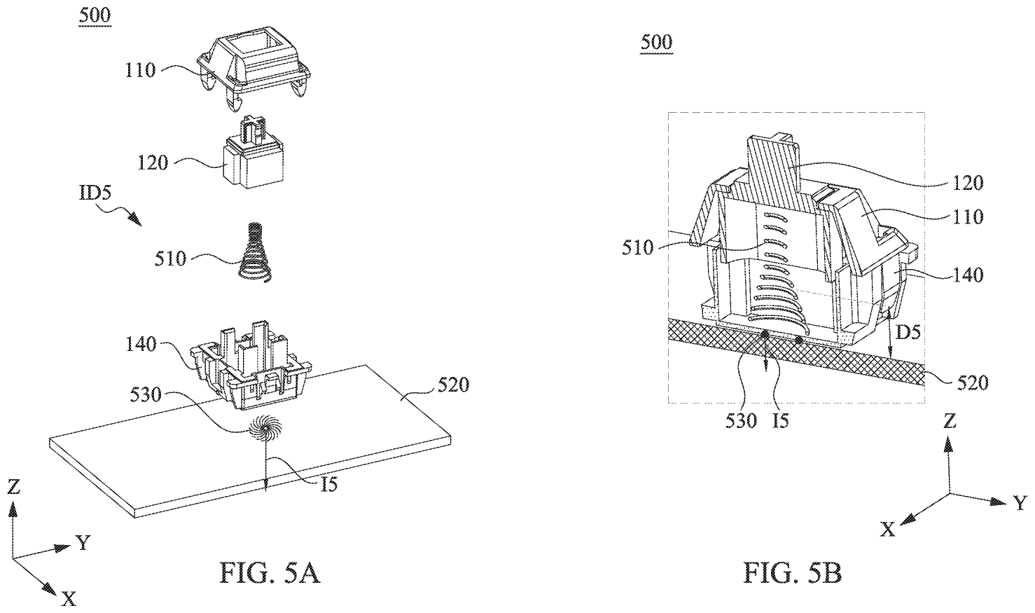

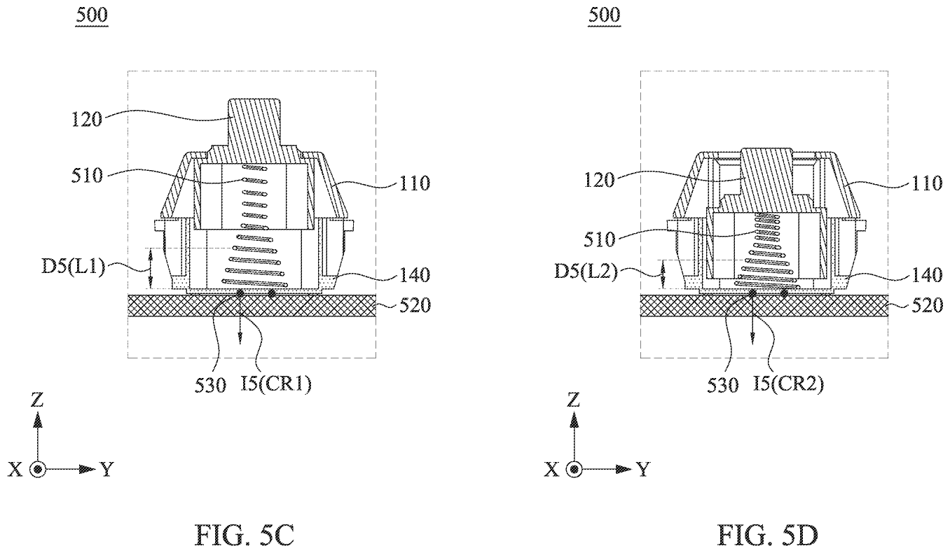

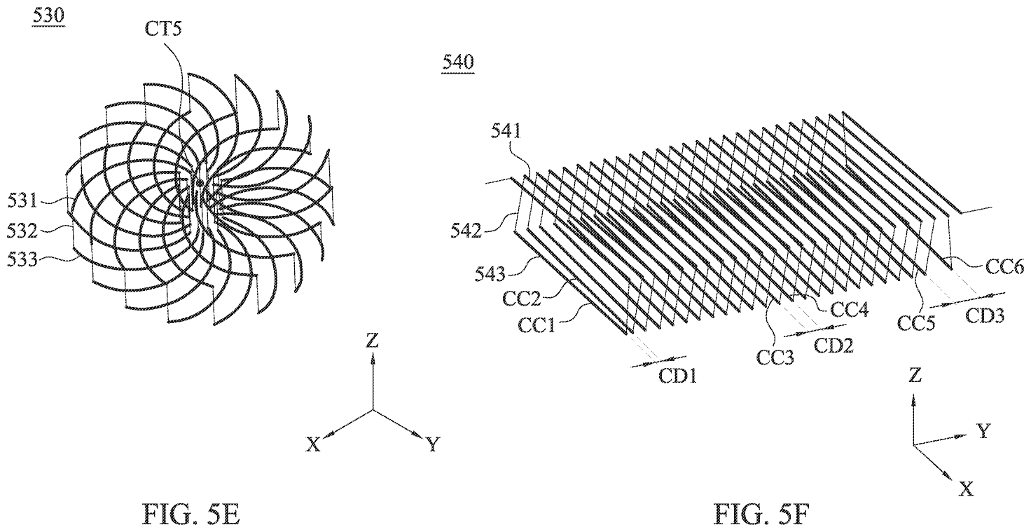

FIG. 5A is an exploded diagram of a switch device 500 illustrated according to some embodiments of present disclosure. Referring to FIG. 5A and FIG. 1A, the switch device 500 is an alternative embodiment of the switch 100. Some elements of the switch device 500 follows a similar labeling convention to that of the switch device 100. For brevity, the discussion will focus more on differences between the switch device 500 and the switch device 100 than on similarities.

Referring to FIG. 5A and FIG. 1A, the switch device 500 includes a magnetizer 510, a PCB 520 and a coil structure 530 instead of the spring 130 and the PCB 150. Along the Z direction, the magnetizer 510 is located between the slide body 120 and the switch bottom cover 140, the switch bottom cover 140 is located between the magnetizer 510 and the PCB 520, and at least a part of the coil structure 530 is located between the PCB 520 and the switch bottom cover 140. In some embodiments, the coil structure 510 can be implemented by metal (such as, copper foil) or other conductors, and the magnetizer 510 can be implemented by an iron powder core or other magnetic material having a spring shape.

In some embodiments, the magnetizer 510 and the coil structure 530 are formed as an inductor ID5, and the coil structure 530 is configured to generate a switch signal 15 according to the inductor ID5. An inductance of the inductor ID5 is associated with a distance D5 (as shown in FIG. 5B to FIG. 5D) between the magnetizer 510 and the coil structure 530. When the distance D5 is changed, the switch signal 15 is changed accordingly. In the embodiments with the magnetizer 510 having the spring shape, the inductance of the inductor ID5 is also associated with a spring interval of the magnetizer 510. When a height of the magnetizer 510 along the Z direction, the spring interval of the magnetizer 510 is changed, such that the inductance of the inductor ID5 is changed. In some embodiments, the switch signal 15 is the current signal flowing through the coil structure 530. The PCB 520 is configured to receive the switch signal IS, and transmit the switch signal 15 to a processor. The switch signal 15 corresponds to the switch signal 11 shown in FIG. 1A.

In some embodiments, the magnetizer 510 can be formed by multiple spring coils with different sizes, and a size of at least one spring coil of the magnetizer 510 on the X-Y plane corresponds to a size of the coil structure 530 on the X-Y plane. In some embodiments, a shape of the coil structure 530 on the X-Y plane is approximately a circle shape. In various embodiments, the magnetizer 510 and the coil structure 530 have various shapes.

FIG. 5B is a three-dimension structural diagram of a cross section of the switch device 500 illustrated according to some embodiments of present disclosure. As illustratively shown in FIG. 5B, each of the switch top cover 110 and the switch bottom cover 140 surrounds the slide body 120 and the magnetizer 510 on the X-Y plane. The slide body 120 surrounds the magnetizer 510 on the X-Y plane, and contacts the magnetizer 510 along the Z direction. In some embodiments, the slide body 120 is configured to move along the Z direction to press the magnetizer 510, such that the distance D5 is reduced.

In some embodiments, the distance D5 corresponds to a distance between one point of the magnetizer 510 and the coil structure 530. For example, the distance D5 can be the distance between the center of mass of the magnetizer 510 and the coil structure 530. In some embodiments, the distance D5 can also be the distance between a spring coil of the magnetizer 510 and the coil structure 530.

FIG. 5C is a two-dimension cross section diagram of the switch device 500 illustrated according to some embodiments of present disclosure. The embodiments shown in FIG. 5C correspond to the unpressed state of the switch device 500. As illustratively shown in FIG. 5C, each of the distance D5 has the length L1. At this moment, the inductor ID5 has an inductance corresponding to the length L1, and the switch signal 15 has the current value CR1 corresponds to the length L1.

FIG. 5D is a two-dimension cross section diagram of the switch device 500 illustrated according to some embodiments of present disclosure. The embodiments shown in FIG. 5D correspond to the pressed state of the switch device 500. As illustratively shown in FIG. 5D, distance D5 has a length L2. At this moment, the inductor ID5 has an inductance corresponding to the length L2, and the switch signal 15 has a current value CR2 corresponds to the length L2.

FIG. 5E is a three-dimension schematic diagram of the coil structure 530 shown in FIG. 5A, illustrated according to some embodiments of present disclosure. As illustratively shown in FIG. 5E, the coil structure 530 includes upper conductive lines 531, via conductive lines 532 and lower conductive lines 533.

As illustratively shown in FIG. 5E, on the X-Y plane, the coil structure 530 has a center CT5, and each of the upper conductive lines 531 and the lower conductive lines 533 includes multiple conductive lines extend outward from the center CT5 with a radian. The via conductive lines 532 includes multiple conductive lines extend along the Z direction and have the same distance with the center CT5 on the X-Y plane. Along the Z direction, the via conductive lines 532 are located between the upper conductive lines 531 and the lower conductive lines 533, and are configured to connect the upper conductive lines 531 and the lower conductive lines 533.

Referring to FIG. 5A and FIG. 5E, along the Z direction, the upper conductive lines 531 and the lower conductive lines 533 are located at two sides of the PCB 520, respectively. Alternatively stated, the PCB 520 is located between the upper conductive lines 531 and the lower conductive lines 533. The via conductive lines 532 connect the upper conductive lines 531 and the lower conductive lines 533 through the PCB 520.

FIG. 5F is a three-dimension schematic diagram of a coil structure 540 illustrated according to some embodiments of present disclosure. As illustratively shown in FIG. 5F, the coil structure 540 includes upper conductive lines 541, via conductive lines 542 and lower conductive lines 543. Referring to FIG. 5F and FIG. 5E, the coil structure 540 is an alternative embodiment of the coil device 530. In various switch devices, the coil structure 540 and the coil structure 530 can be replaced by each other. The upper conductive lines 541, the via conductive lines 542 and the lower conductive lines 543 correspond to the upper conductive lines 531, the via conductive lines 532 and the lower conductive lines 533, respectively.

As illustratively shown in FIG. 5F, the each of the upper conductive lines 541 and the lower conductive lines 543 includes multiple conductive lines extend along the X direction. The via conductive lines 542 includes multiple conductive lines extend along the Z direction. The via conductive lines 542 are located between the upper conductive lines 541 and the lower conductive lines 543, and are configured to connect the upper conductive lines 541 and the lower conductive lines 543.

Referring to FIG. 5A and FIG. 5F, along the Z direction, the upper conductive lines 541 and the lower conductive lines 543 are located at the two sides of the PCB 520, respectively. Alternatively stated, the PCB 520 is located between the upper conductive lines 541 and the lower conductive lines 543. The via conductive lines 542 connect the upper conductive lines 541 and the lower conductive lines 543 through the PCB 520.

In some embodiments, the coil intervals of the coil structure 540 are increased along the Y direction. As illustratively shown in FIG. 5F, the coil structure 540 includes coils CC1-CC6. The coils CC1-CC6 are formed by corresponding conductive lines of the upper conductive lines 541, the via conductive lines 542 and the lower conductive lines 543, and are arranged along the Y direction in order. The coils CC1 and CC2 are adjacent with each other and have a coil interval CD1 in between, the CC3 and CC4 are adjacent with each other and have a coil interval CD2 in between, and the CC5 and CC6 are adjacent with each other and have a coil interval CD3 in between. In which the coil interval CD3 is larger than the coil interval CD2, and the coil interval CD2 is larger than the coil interval CD1.

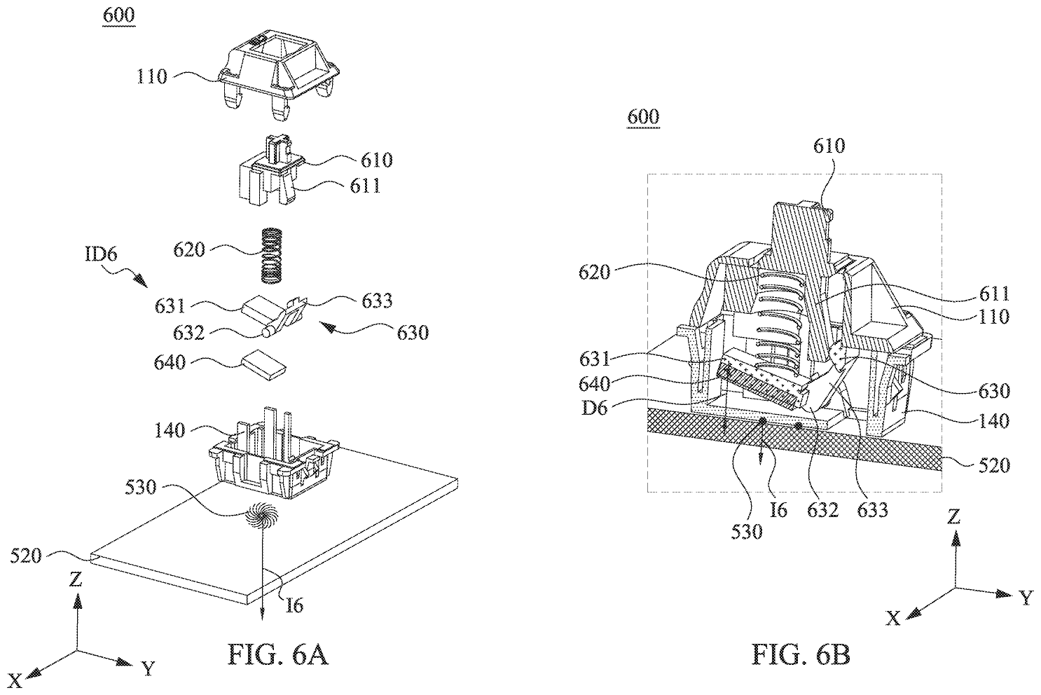

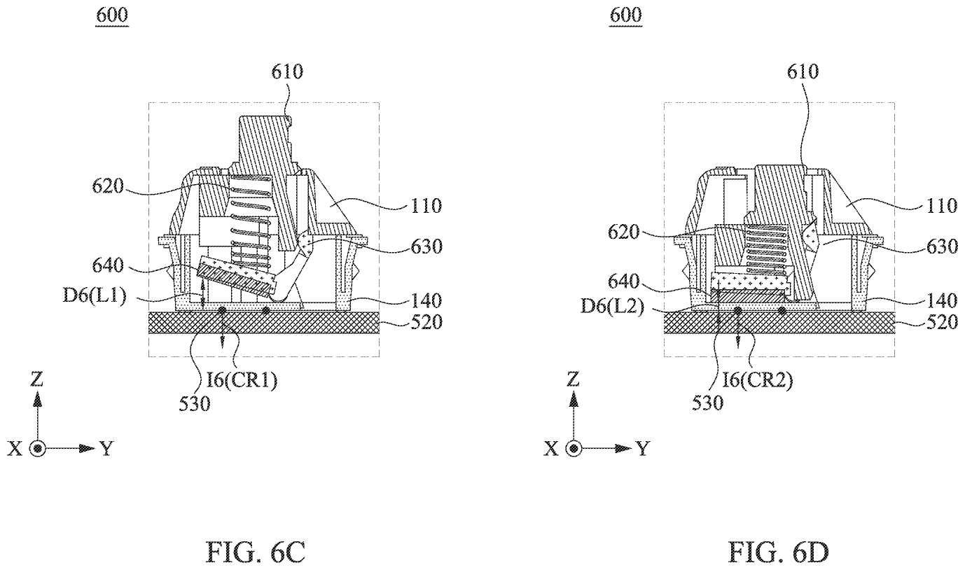

FIG. 6A is an exploded diagram of a switch device 600 illustrated according to some embodiments of present disclosure. Referring to FIG. 6A and FIG. 5A, the switch device 600 is an alternative embodiment of the switch 100. Some elements of the switch device 600 follows a similar labeling convention to that of the switch device 500. For brevity, the discussion will focus more on differences between the switch device 600 and the switch device 500 than on similarities.

Referring to FIG. 6A and FIG. 5A, the switch device 600 includes a slide body 610, a spring 620, a rotate body 630 and a magnetizer 640 instead of the slide body 120 and the magnetizer 510. Along the Z direction, the switch bottom cover 140, the magnetizer 640, the rotate body 630, the spring 620 and the slide body 610 are arranged in order. In some embodiments, the magnetizer 610 can be implemented by an iron powder core or other magnetic material.

As illustratively shown in FIG. 6A, the slide body 610 includes a extend portion 611 extending along the Z direction. The rotate body 620 include a rotate axis 632 and extend portions 631 and 633. In some embodiments, the extend portions 631 and 633 are approximately perpendicular to each other, and are fixed on the rotate axis 632. In various embodiments, the extend portions 631 and 633 may have various angles in between. A shape of each of the extend portion 631 and the magnetizer 640 is approximately a cuboid. In various embodiments, the extend portion 631 and the magnetizer 640 may have various shapes.

In some embodiments, the magnetizer 640 and the coil structure 530 are formed as an inductor ID6, and the coil structure 530 is configured to generate a switch signal 16 according to the inductor ID6. An inductance of the inductor ID6 is associated with a distance D6 (as shown in FIG. 6B to FIG. 6D) between the magnetizer 610 and the coil structure 530. When the distance D6 is changed, the switch signal 16 is changed accordingly. In some embodiments, the switch signal 16 is the current signal flowing through the coil structure 530. The PCB 520 is configured to receive the switch signal 16, and transmit the switch signal 16 to a processor. The switch signal 16 corresponds to the switch signal 11 shown in FIG. 1A.

FIG. 6B is a three-dimension structural diagram of a cross section of the switch device 600 illustrated according to some embodiments of present disclosure. As illustratively shown in FIG. 6B, each of the switch top cover 110 and the switch bottom cover 140 surrounds the slide body 610, the spring 620, the rotate body 630 and the magnetizer 640 on the X-Y plane. The slide body 610 contacts the spring 620 along the Z direction. The extend portion 611 contacts the extend portion 633 along the Y direction. The spring 620, the extend portions 611 and 633 are arranged in order along the Y direction.

As illustratively shown in FIG. 6B, a terminal of the spring 620 is fixed at a side of the extend portion 631, and the magnetizer 640 is fixed at another side of the extend portion 631. In some embodiments, the slide body 610 is configured to move along the Z direction to press the spring 620, such that the spring 620 presses the extend portion 631 along the Z direction. When the extend portion 631 is pressed by the spring 620, the extend portion 631 rotates on the Z-Y plane with the rotate axis 632 as the center, such that the distance D6 is decreased.

FIG. 6C is a two-dimension cross section diagram of the switch device 600 illustrated according to some embodiments of present disclosure. The embodiments shown in FIG. 6C correspond to the unpressed state of the switch device 600. As illustratively shown in FIG. 6C, each of the distance D6 has the length L1. At this moment, the inductor ID6 has an inductance corresponding to the length L1, and the switch signal 16 has the current value CR1 corresponds to the length L1.

FIG. 6D is a two-dimension cross section diagram of the switch device 600 illustrated according to some embodiments of present disclosure. The embodiments shown in FIG. 6D correspond to the pressed state of the switch device 600. As illustratively shown in FIG. 6D, distance D6 has a length L2. At this moment, the inductor ID6 has an inductance corresponding to the length L2, and the switch signal 16 has a current value CR2 corresponds to the length L2.

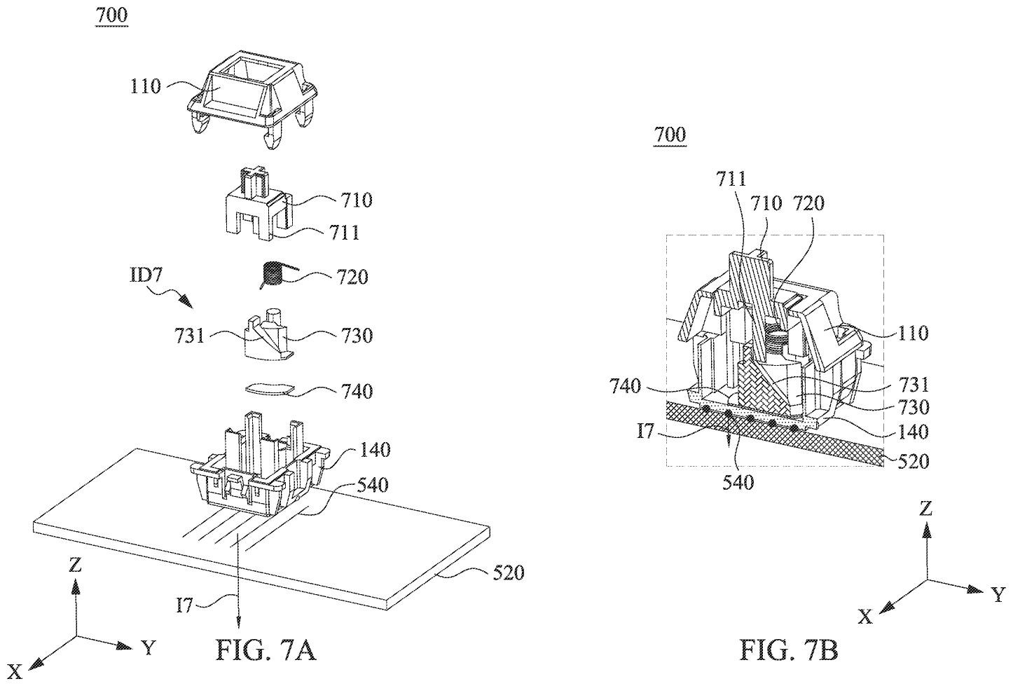

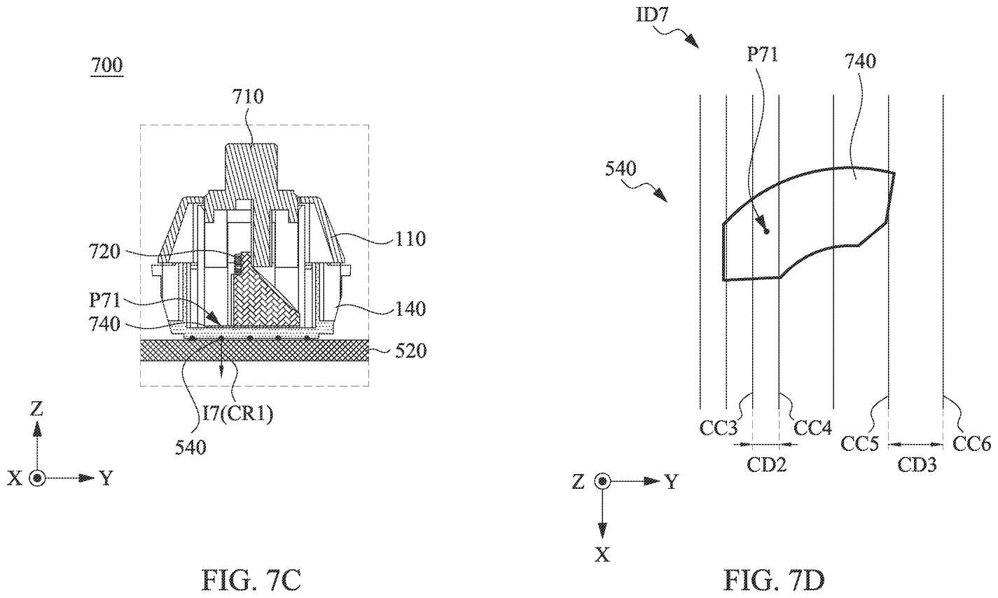

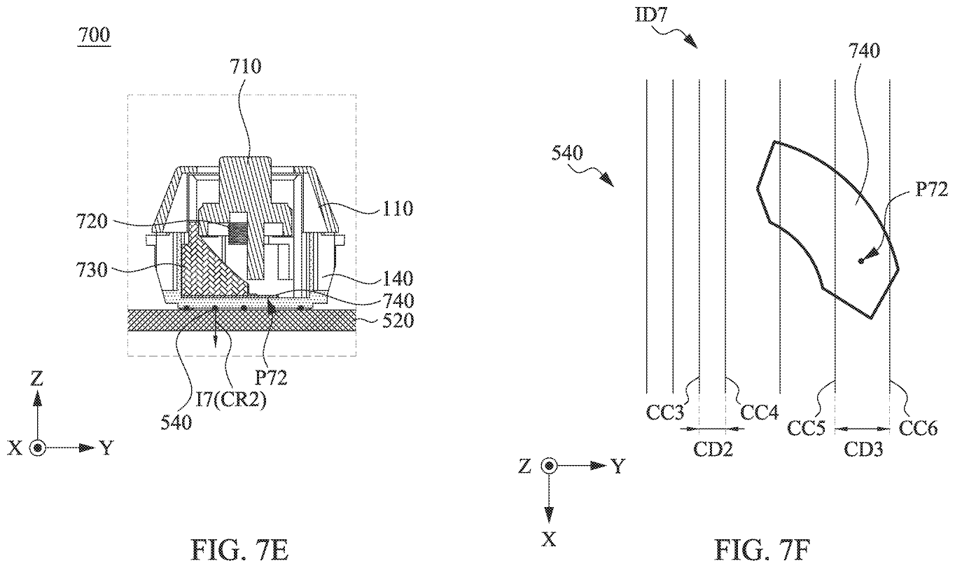

FIG. 7A is an exploded diagram of a switch device 700 illustrated according to some embodiments of present disclosure. Referring to FIG. 7A and FIG. 5A, the switch device 700 is an alternative embodiment of the switch 100. Some elements of the switch device 700 follows a similar labeling convention to that of the switch device 500. For brevity, the discussion will focus more on differences between the switch device 700 and the switch device 500 than on similarities.

Referring to FIG. 7A and FIG. 5A, the switch device 700 includes a slide body 710, a torsion spring 720, a rotate body 730, a magnetizer 740 and the coil structure 540 instead of the slide body 120, the magnetizer 510 and the coil structure 530. Along the Z direction, the switch bottom cover 140, the magnetizer 740, the rotate body 730, the torsion spring 720 and the slide body 710 are arranged in order. At least a part of the coil structure 540 is located between the switch bottom 140 and the PCB 520. In some embodiments, the magnetizer 740 can be implemented by an iron powder core or other magnetic material. In some embodiments, the coil structure 540 can be formed by arrangements of circuits on the PCB 520.

As illustratively shown in FIG. 7A, the slide body 710 includes a extend portion 711 extending along the Z direction. The rotate body 730 include an inclined plane structure 731. In some embodiments, the magnetizer 740 and the coil structure 540 are formed as an inductor ID7, and the coil structure 540 is configured to generate a switch signal 17 according to the inductor ID7. An inductance of the inductor ID7 is associated with a coil interval of the coil structure 540 corresponding to the magnetizer 740. Referring to FIG. 5F, the coil intervals of the coil structure 540 is changed gradually along the Y direction. Correspondingly, when the magnetizer 740 moves along the Y direction, the switch signal 17 is changed respectively. In some embodiments, the switch signal 17 is the current signal flowing through the coil structure 540. The PCB 520 is configured to receive the switch signal 17, and transmit the switch signal 17 to a processor. The switch signal 17 corresponds to the switch signal 11 shown in FIG. 1A.

FIG. 7B is a three-dimension structural diagram of a cross section of the switch device 700 illustrated according to some embodiments of present disclosure. As illustratively shown in FIG. 7B, each of the switch top cover 110 and the switch bottom cover 140 surrounds the slide body 710, the torsion spring 720, the rotate body 730 and the magnetizer 740 on the X-Y plane. The slide body 710 contacts the torsion spring 720 along the Z direction. The extend portion 711 contacts the inclined plane structure 731. The torsion spring 720 and 740 are fixed on opposite terminals of the rotate body 730, respectively, along the Z direction.

In some embodiments, the slide body 710 is configured to move along the Z direction to press the torsion spring 720, such that the torsion spring 720 rotates the rotate body 730 on the X-Y plane, to move the magnetizer 740.

FIG. 7C is a two-dimension cross section diagram of the switch device 700 illustrated according to some embodiments of present disclosure. In FIG. 7C, the X direction points out from the paper. The embodiments shown in FIG. 7C corresponds to the unpressed state of the switch device 700. At this moment, the magnetizer 740 is located at a position P71.

FIG. 7D is a top view diagram of the magnetizer 740 and the coil structure 540 shown in FIG. 7C illustrated according to some embodiments of present disclosure. In FIG. 7D, the Z direction points out from the paper.

Referring to FIG. 5F, FIG. 7C and FIG. 7D, when the switch device 700 is unpressed, the magnetizer 740 is located at the position P71 corresponding to the coils CC3 and CC4. In some embodiments, the position P71 is located between the coils CC3 and CC4. At this moment, the inductor ID7 has an inductance corresponding to the coil interval CD2, and the switch signal 17 has the current value CR1 corresponding to the coil interval CD2.

FIG. 7E is a two-dimension cross section diagram of the switch device 700 illustrated according to some embodiments of present disclosure. In FIG. 7E, the X direction points out from the paper. The embodiments shown in FIG. 7E corresponds to the pressed state of the switch device 700. At this moment, the magnetizer 740 is located at a position P72.

FIG. 7F is a top view diagram of the magnetizer 740 and the coil structure shown 540 in FIG. 7E illustrated according to some embodiments of present disclosure. In FIG. 7E, the Z direction points out from the paper.

Referring to FIG. 5F, FIG. 7E and FIG. 7F, when the switch device 700 is pressed, the magnetizer 740 is located at the position P72 corresponding to the coils CC5 and CC6. In some embodiments, the position P72 is located between the coils CC5 and CC6. At this moment, the inductor ID7 has an inductance corresponding to the coil interval CD3, and the switch signal 17 has the current value CR2 corresponding to the coil interval CD3.

In some embodiments, the switch device 700 can also change the inductor ID7 by changing a corresponding area between the magnetizer 740 and the coil structure 540. Descriptions are made by examples following with the coils CC5 and CC6 of the coil structure 540.

Referring to FIG. 7D, when the switch device 700 is unpressed, an overlapped area of the magnetizer 740 and the coils CC5, CC6 is smaller, such that the inductance corresponding to the magnetizer 740 and the coils CC5, CC6 is smaller.

Referring to FIG. 7F, when the switch device 700 is pressed, an overlapped area of the magnetizer 740 and the coils CC5, CC6 is larger, such that the inductance corresponding to the magnetizer 740 and the coils CC5, CC6 is larger.

In summary, the present disclosure provides various switch devices forming inductors with various structures and changing inductance by pressing to change states of switch signals. As a result, users can use switch devices with various structures according to various specification requirements.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A switch device, comprising:
at least one spring configured to generate a switch signal corresponding to an inductance of the at least one spring, and comprising a first portion and a second portion arranged along a first direction, wherein the inductance is associated with a first interval between the first portion and the second portion;
a slide body configured to move along the first direction to change the first interval; and
a circuit board configured to receive the switch signal,
wherein the at least one spring is located between the slide body and the circuit board.

2. The switch device of claim 1, wherein the at least one spring further comprises:
a third portion and a fourth portion arranged along the first direction; and
a connect portion extending along a second direction different from the first direction, and configured to connect the first portion and the third portion,
wherein the first portion and the third portion are arranged along the second direction.

3. The switch device of claim 2, wherein the second portion and the fourth portion are arranged along the second direction, and
the inductance is further associated with a second interval between the third portion and the fourth portion.

4. The switch device of claim 1, wherein the at least one spring further comprises:
a first spring comprising a contact portion, the first portion and the second portion; and
a second spring comprising a third portion and a fourth portion arranged along the first direction,
wherein the contact portion extends along a second direction different from the first direction, and is configured to contact the second spring along the first direction.

5. The switch device of claim 4, wherein the first spring and the second spring are arranged along the second direction, and
the inductance is further associated with a second interval between the third portion and the fourth portion.

6. The switch device of claim 1, wherein the at least one spring further comprises:
a first spring comprising the first portion and the second portion;
a second spring comprising a third portion and a fourth portion arranged along the first direction; and
a conductive sheet located between the slide body and each of the first spring and the second spring, and configured to couple the first spring and the second spring in series.

7. The switch device of claim 6, wherein the first spring and the second spring are arranged along a second direction, and
the inductance is further associated with a second interval between the third portion and the fourth portion.

8. The switch device of claim 1, wherein the at least one spring further comprises:
a first spring comprising the first portion and the second portion; and
a second spring comprising a third portion and a fourth portion arranged along the first direction, wherein the second spring is coupled in series with the first spring, and is surrounded by the first spring,
wherein the inductance is further associated with a second interval between the third portion and the fourth portion.

9. The switch device of claim 1, wherein
the switch signal has a first current value when the first interval has a first length,
the switch signal has a second current value when the first interval has a second length,
the first current value is different from the second current value, and
the first length is different from the second length.

10. The switch device of claim 9, wherein
the switch signal has a third current value when the first interval has a third length,
the third current value is between the first current value and the second current value,
the third length is between the first length and the second length, and
the third current value corresponds to a state between a pressed state of the switch device and an unpressed state of the switch device.

11. A switch device, comprising:
a magnetizer;
a coil structure comprising a plurality of first conductive lines and a plurality of second conductive lines, being formed as an inductor with the magnetizer, and configured to generate a switch signal according to the inductor;
a slide body configured to move the magnetizer to change the inductor; and
a circuit board located between the plurality of first conductive lines and the plurality of second conductive lines, and configured to receive the switch signal.

12. The switch device of claim 11, wherein the magnetizer has a spring shape and is located between the slide body and the coil structure, and
the slide body is further configured to press the magnetizer to change the inductor.

13. The switch device of claim 11, further comprising:
a rotate body located between the slide body and the magnetizer, wherein the magnetizer is fixed on the rotate body; and
a spring located between the slide body and the rotate body, fixed on the rotate body, and configured to be pressed by the slide body to rotate the rotate body.

14. The switch device of claim 11, further comprising:
a rotate body located between the slide body and the magnetizer along a first direction, and configured to rotate on a plane perpendicular to the first direction, wherein the magnetizer is fixed on the rotate body.

15. The switch device of claim 14, wherein the coil structure has a first coil interval and a second coil interval different from each other, and
the rotate body is further configured to rotate the magnetizer from a first position corresponding to the first coil interval to a second position corresponding to the second coil interval, to change the inductor.

16. A method of operating a switch device, comprising:
pressing at least one spring to adjust a first interval between a first portion of the at least one spring and a second portion of the at least one spring;
generating a switch signal having a first current value from the spring to a circuit board when the first interval has a first length; and
generating the switch signal having a second current value from the spring to the circuit board when the first interval has a second length,
wherein the first current value is different from the second current value, and
the first length is different from the second length.

17. The method of claim 16, further comprising:
moving a slide body along a first direction to press the at least one spring;
adjusting a second interval between a third portion of the at least one spring and a fourth portion of the at least one spring;
generating the switch signal having the first current value when the second interval has the first length; and
generating the switch signal having the second current value when the second interval has the second length,
wherein the third portion and the fourth portion are arranged along the first direction,
the third portion and the first portion are arranged along a second direction, and
the second direction is approximately perpendicular with the first direction.

18. The method of claim 16, further comprising:
moving a slide body along a first direction to press the at least one spring;
adjusting a second interval between a third portion of the at least one spring and a fourth portion of the at least one spring;
generating the switch signal having the first current value when the second interval has the first length; and
generating the switch signal having the second current value when the second interval has the second length,
wherein the first portion and the second portion are included in a first spring of the at least one spring,
the third portion and the fourth portion are included in a second spring of the at least one spring,
the first spring includes a contact portion extending along a second direction and contact the second spring along the first direction, and
the second direction is approximately perpendicular with the first direction.

19. The method of claim 16, further comprising:
moving a slide body along a first direction to press the at least one spring;
adjusting a second interval between a third portion of the at least one spring and a fourth portion of the at least one spring;
generating the switch signal having the first current value when the second interval has the first length;
generating the switch signal having the second current value when the second interval has the second length; and
coupling a first spring of the at least one spring and a second spring of the at least one spring in series by a conductive sheet,
wherein the first portion and the second portion are included in the first spring,
the third portion and the fourth portion are included in the second spring,
the conductive sheet extends along a second direction and is located between the at least one spring and the slide body along the first direction, and
the second direction is approximately perpendicular with the first direction.

20. The method of claim 16, further comprising:
moving a slide body to press the at least one spring;
adjusting a second interval between a third portion of the at least one spring and a fourth portion of the at least one spring;
generating the switch signal having the first current value when the second interval has the first length;
generating the switch signal having the second current value when the second interval has the second length; and
coupling a first spring of the at least one spring and a second spring of the at least one spring in series,
wherein the first portion and the second portion are included in the first spring,
the third portion and the fourth portion are included in the second spring, and
the second spring is surrounded by the first spring.
